(19) United States
(12) Patent Application Publication
(10) Pub. No.: US 2019/0267562 A1
(43) Pub. Date: Aug. 29, 2019

(54) LAMINATE COMPRISING PHOTOVOLTAIC CELL

(71) Applicant: THE DILLER CORPORATION, Cincinnati, OH (US)

(72) Inventor: Kevin Francis O'Brien, Cincinnati, OH (US)

(73) Assignee: THE DILLER CORPORATION, Cincinnati, OH (US)

(21) Appl. No.: 15/908,795

(22) Filed: Feb. 28, 2018

(51) Int. Cl. H01L 51/44; H01L 51/00

(52) U.S. Cl. CPC H01L 51/448; H01L 51/0026; H01L 51/005; H01L 51/0045

(57) ABSTRACT

A laminate with a photovoltaic cell (e.g., an organic photovoltaic cell, or an inorganic photovoltaic cell) embedded within the laminate includes a first paper layer; a first electrically-conductive layer comprising an electrically-conductive material, the first electrically-conductive layer being disposed over the first paper layer; at least one photovoltaic active material layer disposed over the first electrically-conductive layer; a second electrically-conductive layer comprising a translucent electrically-conductive material, the second electrically-conductive layer being disposed over the photovoltaic active material layer; a translucent insulating layer disposed over the second electrically-conductive layer, wherein the first paper layer and the translucent insulating layer encapsulate the photovoltaic cell comprising the first electrically-conductive layer, the photovoltaic active material layer, and the second electrically-conductive layer within the laminate.

### FIELD OF THE INVENTION

The disclosure generally relates to laminates comprising photovoltaic cells. More particularly, the disclosure relates to a laminate with a photovoltaic cell (e.g., an organic photovoltaic cell, or an inorganic photovoltaic cell) embedded within the laminate.

### BACKGROUND OF THE INVENTION

Decorative laminates have been used as surfacing materials for many years, in both commercial and residential applications, where pleasing aesthetic effects in conjunction with desired functional behavior (such as superior wear, heat and stain resistance, cleanability and cost) are preferred. Typical applications have historically included furniture, kitchen countertops, table tops, store fixtures, bathroom vanity tops, cabinets, wall paneling, office partitions, and the like.

Laminates are useful as surfacing materials, including as decorative surfaces, in many situations due to their combination of desirable qualities (e.g., superior wear, heat and stain resistance, cleanability, and cost). Laminate surfaces are composed of discrete layers, such as layers of resin-impregnated kraft paper that are pressed to form the laminate. One conventional decorative laminate is made by stacking three sheets of treated kraft paper (e.g., three sheets of phenol-formaldehyde resin-impregnated kraft paper), dry decorative paper (e.g., a print sheet), and a sheet of treated overlay paper (e.g. melamine-formaldehyde resin-impregnated tissue paper or acrylic resin-impregnated tissue paper), one on top of another and then bonding the stacked sheets together with heat and pressure.

A high-pressure laminate process (HPL) is an irreversible thermal process wherein a “laminate stack” including resin-impregnated sheets of kraft paper undergoes a simultaneous pressing and heating process at relatively high levels of heat and pressure, such as temperatures greater than or equal to 125° C. and at least 5 mega Pascals (MPa) of pressure, typically for a press cycle of 30-50 minutes. Every press cycle includes both heating and cooling of the press platens. An HPL process contrasts with low pressure laminate processes (LPL) that are conducted at pressures of less than 5.0 MPa, typically between 2-3 MPa.

Photovoltaic cells (PVs) advantageously directly convert incident light into electricity, with no noise, pollution, or moving parts, making them environmentally friendly, robust, reliable and long lasting. An organic photovoltaic (OPV) cell is a type of PV cell that uses conductive organic polymers or small organic molecules for light absorption and charge transport to produce electrical energy from light by the photovoltaic effect. Inorganic photovoltaic cells based on inorganic materials such as crystalline silicon, amorphous silicon, CdTe, and Cu(In,Ga)Se₂ are also well known. A representative conventional OPV cell comprises a number of layers, in series, a transparent (or at least translucent) anode, for example, a layer of a transparent (or at least translucent) conductive oxide such as an indium tin oxide (ITO), a layer of poly(3,4-ethylenedioxythiophene) polystyrene sulfonate (PEDOT:PSS), one or more active layers, and a cathode, for example, a layer of aluminum. An electron blocking layer may be provided between the anode and the active layer(s) and/or a hole blocking layer may be provided between the cathode and the active layer(s). The aluminum may be deposited on a polymer substrate, such as a polyethylene terephthalate (PET) substrate, and the ITO may be protected by a transparent encapsulating layer. The active layer(s) commonly comprise two distinct organic semiconductors, one being an electron donor material and the other an electron acceptor material. The active layer(s) can either be provided as a single layer comprising a mixture of the electron donor and electron acceptor materials or as a bilayer in which the electron donor and electron acceptor materials are present as separate, distinct, adjacent layers. Because the anode is transparent (or at least translucent), sunlight can pass there through and be absorbed by the active layer(s). When a photon is absorbed by the electron donor and electron acceptor materials, an exciton is formed. The exciton then diffuses to an interface between the donor and acceptor materials and an electron is transferred to the acceptor or a hole is transferred to the donor (depending on which material absorbed the photon). This results in a charge-transfer state in which the charges reside on different molecules (or functional groups) but remain bound by coulombic attraction. The charge-transfer state dissociates into two types of charge-carriers, electrons and holes, which eventually travel to the cathode and anode, respectively. The direction of travel of the different types of charge-carriers is modulated by a difference in work function of the two electrodes.

OPV cells with an inverted architecture are also known. In an inverted photovoltaic cell, the charge carriers exit the device in the opposite direction as in a normal device because the positions of the anode and cathode electrodes (and also any hole blocking layers and/or electron blocking layers) are switched. Thus, the cathode is transparent (or at least translucent) in an inverted cell. In an inverted cell, a transparent (or at least translucent) conductive oxide may be used as the cathode and a relatively high work function metal such as gold or silver may be used as the anode. Inverted OPV cells are advantageous in that inverted OPVs may have longer lifetimes than regularly structured or conventional OPVs, but regular OPV's typically exhibit better efficiency.

Degradation of the various organic materials in OPV's is known to occur because of the permeation of water and oxygen into the OPV device. Therefore, it is useful to provide OPV's with protective encapsulation layers having extremely low water vapor and oxygen permeability.

### SUMMARY OF THE DISCLOSURE

This summary is provided to introduce a selection of concepts in a simplified form that is further described in the Detailed Description. This summary is not intended to identify key features or essential features of the claimed subject matter, nor is it intended to be used to limit the scope of the claimed subject matter.

A laminate with a photovoltaic cell (e.g., an organic photovoltaic cell, or an inorganic photovoltaic cell) embedded within the laminate, comprising a first paper layer, a first electrically-conductive layer comprising an electrically-conductive material, the first electrically-conductive layer being disposed over the first paper layer, at least one photovoltaic active material layer disposed over the first electrically-conductive layer, a second electrically-conductive layer comprising a translucent electrically-conductive material, the second electrically-conductive layer being disposed over the photovoltaic active material layer, a translucent insulating layer disposed over the second electrically-conductive layer, wherein the first paper layer and the translucent insulating layer encapsulate the photovoltaic cell comprising the first electrically-conductive layer, the photovoltaic active material layer, and the second electrically-conductive layer within the laminate.

A method for manufacturing a laminate with a photovoltaic cell (e.g., an organic photovoltaic cell, or an inorganic photovoltaic cell) embedded within the laminate, the method comprising providing a first paper layer, disposing a first electrically-conductive layer over the first paper layer, wherein the first electrically-conductive layer comprises an electrically-conductive material, disposing at least one photovoltaic active material layer over the first electrically-conductive layer, disposing a second electrically-conductive layer over the photovoltaic active material layer, wherein the second electrically-conductive layer comprises a translucent electrically-conductive material, disposing a translucent insulating layer over the second electrically-conductive layer, compressing and, heating during at least a portion of the compressing, a laminate stack comprising at least the first paper layer, the first electrically-conductive layer, the photovoltaic active material layer, the second electrically-conductive layer, and the translucent insulating layer according to a lamination process, thereby manufacturing the laminate with the photovoltaic cell.

### BRIEF DESCRIPTION OF THE DRAWINGS

FIG. 1 is a schematic diagram of an example of a laminate surfacing material integrated into a panel for exterior use with at least one photovoltaic cell embedded or disposed within the laminate structure, the at least one photovoltaic cell comprising multiple layers;

FIG. 2 shows an example of a laminate having a photovoltaic cell embedded or disposed within the laminate structure;

FIG. 3 generally illustrates example operations for forming an electrical via between layers in a laminate using a masking technique;

FIG. 4 generally illustrates example operations for forming an electrical via between layers in a laminate using a hole cutting technique; and

FIG. 5 shows I-V characteristics of a laminate having a photovoltaic cell embedded or disposed within the laminate structure.

### DETAILED DESCRIPTION

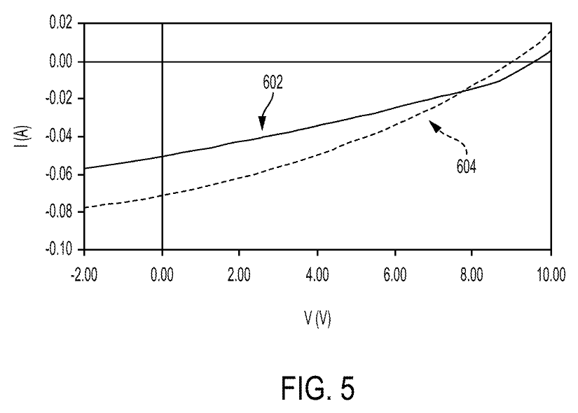

A laminate with a photovoltaic cell embedded therein, i.e., incorporated and encapsulated therein, is provided herein. Surprisingly, and unexpectedly, a photovoltaic cell embedded within a laminate performed better in some respects than a comparable photovoltaic cell not incorporated and encapsulated within a laminate, even though the exemplary photovoltaic cell embedded within the laminate included an additional translucent insulating layer (between incident light and the photovoltaic cell active layer) that one of ordinary skill would expect to significantly reduce cell efficiency and performance. As such, it was expected that I-V characteristics associated with the photovoltaic cell embedded within a laminate would be markedly inferior to I-V characteristics associated with a comparable encapsulated photovoltaic cell that was not embedded within a laminate and that did not include an additional translucent insulating layer. However, as is shown herein with reference to FIG. 5, a photovoltaic cell embedded within a laminate, despite having an additional translucent insulating layer, was surprisingly and unexpectedly found to have superior I-V characteristics relative to a comparable encapsulated photovoltaic cell that was not embedded within a laminate and that did not include an additional translucent insulating layer. Of course, further device performance enhancement is expected when an organic photovoltaic device is constructed and arranged without an additional translucent insulating layer in accordance with embodiments of the invention as described herein.

A laminate with a photovoltaic cell incorporated and encapsulated within the laminate, the laminate comprising a first paper layer, a first electrically-conductive layer comprising an electrically-conductive material, the first electrically-conductive layer being disposed over the first paper layer, at least one photovoltaic active material layer disposed over the first electrically-conductive layer, a second electrically-conductive layer comprising a translucent electrically-conductive material, the second electrically-conductive layer being disposed over the photovoltaic active material layer, and a translucent insulating layer disposed over the second electrically-conductive layer, wherein the first paper layer and the translucent insulating layer encapsulate the photovoltaic cell comprising the first electrically-conductive layer, the photovoltaic active material layer, and the second electrically-conductive layer within the laminate, is disclosed.

It should be understood that a translucent layer as described herein is translucent at least to photons capable of exciting the photovoltaic active material(s) present in the laminate with a photovoltaic cell incorporated and encapsulated within the laminate. Thus, in embodiments, a translucent layer may be translucent to selected wavelengths of light and not translucent to other wavelengths of light.

In embodiments, the first paper layer has at least first and second vias through the first paper layer, and the first electrically-conductive layer is electrically coupled to a first via and the second electrically-conductive layer is electrically coupled to a second via, the first and second vias including a further electrically-conductive material therein. The first electrically-conductive layer may be electrically coupled to the first via, because the first via makes electrical contact with the first electrically-conductive layer. Similarly, the second electrically-conductive layer may be electrically coupled to the second via, because the second via makes electrical contact with the second electrically-conductive layer. The electrically-conductive material of the first electrically-conductive layer may be the same or different from the further electrically-conductive material of the first and second vias.

In embodiments, the photovoltaic device has a conventional structure and the second electrically conductive layer is an anode electrode and the first electrically conductive layer is a cathode electrode. In alternative embodiments, the photovoltaic device has an inverted structure and the second electrically conductive layer is an cathode electrode and the first electrically conductive layer is an anode electrode.

In embodiments, the translucent insulating layer may comprise a cross-linked polymer, for example, urethane acrylate, polyester acrylate, epoxy acrylate, acrylic acrylate, polyether acrylate, or a mixture thereof.

In embodiments, the laminate may further comprise a decorative layer or paper (also known as a print sheet) between the translucent insulating layer and the first electrically-conductive layer, most typically between the first electrically-conductive layer and the photovoltaic active material layer(s) due to the opacity of the decorative layer. The laminate may also comprise glue film layers, for example, when untreated kraft paper layers are included as further described below.

In preferred embodiments, each of the individual laminate paper layers (e.g., treated kraft paper layers), glue layer(s), and decorative layer(s) are substantially free of conductive powders, other than conductive powders that may be present in any vias. In preferred embodiments, the various laminate sheets when converted into a laminate according to a lamination process such as a high pressure lamination process have a combined resistance greater than 10⁸ ohms, other than the resistance of any vias, In preferred embodiments, each of the individual laminate paper layers are substantially free of humectants including but not limited to glycerin and aliphatic amines. As used herein, “substantially free of” means that only insignificant amounts of the indicated component are permitted. For example, the individual laminate paper layer contains less than 0.5 wt %, less than 0.1 wt %, more preferably less than 0.05 wt %, based on the weight of the paper layer, of the indicated component.

Generally, as used herein, a “photovoltaic active material” is an organic semiconductor known as an electron donor or an electron acceptor. The photovoltaic material is capable of absorbing incident light and, provided that both an electron donor and an electron acceptor are present, is further capable of converting the incident light into electrical energy. The photovoltaic active material layer(s) comprise a combination of an electron donor and an electron acceptor. Thus, in embodiments, the photovoltaic active material layer can be provided as a layer comprising a mixture of distinct electron donor and electron acceptor materials. The photovoltaic active material layer can also be provided as a layer comprising a material including both electron donor and electron acceptor groups. Alternatively, the at least one photovoltaic active material layer can be provided as a bilayer in which the electron donor and electron acceptor materials are present as separate, distinct, adjacent layers. Combinations of the foregoing are also contemplated.

Suitable electron donor materials include but are not limited to small molecule electron donors such as benz[b]anthracene, 2,4-Bis[4-(N,N-dibenzylamino)-2,6-dihydroxyphenyl]squaraine, 2,4-Bis[4-(N,N-diisobutylamino)-2,6-dihydroxyphenyl] squaraine (DIB-SQ), 2,4-Bis[4-(N,N-diphenylamino)-2,6-dihydroxyphenyl]squaraine, 2-[(7-{4-[N,N-Bis(4-methylphenyl)amino]phenyl}-2,1,3-benzothiadiazol-4-yl)methylene]propanedinitrile (DTDCPB), C101 dye, C106 dye, Copper(II) phthalocyanine, D102 dye, D131 dye, D358 dye, 5,10,15,20-Tetraphenylbisbenz[5,6]indeno[1,2,3-cd:1′,2′,3′-lm]perylene (DBP), 5,5″″′-Dihexyl-2,2′:5′,2″:5″,2′″:5′″,2″″:5″″,2″″′-sexithiophene (DH-6T), 2-[7-(4-Diphenylaminophenyl)-2,1,3-benzothiadiazol-4-yl]methylenepropanedinitrile (DPDCPB), 2-{[7-(5-N,N-Ditolylaminothiophen-2-yl)-2,1,3-benzothiadiazol-4-yl]methylene}malononitrile (DTDCTB), 7,7′-[4,4-Bis(2-ethylhexyl)-4H-silolo[3,2-b:4,5-b′]dithiophene-2,6-diyl]bis[6-fluoro-4-(5′-hexyl-[2,2′-bithiophen]-5-yl)benzo[c][1,2,5]thiadiazole] (DTS(FBTTh₂)₂), 4,4′-[4,4-Bis(2-ethylhexyl)-4H-silolo[3,2-b:4,5-b′]dithiophene-2,6-diyl]bis[7-(5′-hexyl-[2,2′-bithiophen]-5-yl)-[1,2,5]thiadiazolo[3,4-c]pyridine] (DTS(PTTh₂)₂), K19 dye, merocyanine dye (HB194), N749 black dye, pentacene, α-Sexithiophene (6T), 2,5-Di-(2-ethylhexyl)-3,6-bis-(5″-n-hexyl-[2,2′,5′,2″]terthiophen-5-yl)-pyrrolo[3,4-c]pyrrole-1,4-dione (SMDPPEH), 2,5-Dioctyl-3,6-bis-(5″-n-hexyl-[2,2′,5′,2″]terthiophen-5-yl)-pyrrolo[3,4-c]pyrrole-1,4-dione (SMDPPO), Tin(IV) 2,3-naphthalocyanine dichloride (SnNcCl₂), Tris[4-(5-dicyanomethylidenemethyl-2-thienyl)phenyl]amine (TDCV-TPA), Zinc phthalocyanine (ZnPc), and 5,5″″-Bis(2″″′,2″″′-dicyanovinyl)-2,2′:5′,2″:5″,2′″:5′″,2″″-quinquethiophene (DCV5T); polymer electron donors such as Poly[2-methoxy-5-(3′,7′-dimethyloctyloxy)-1,4-phenylenevinylene] (MDMO-PPV), Poly[2-methoxy-5-(2-ethylhexyloxy)-1,4-phenylenevinylene] (MEH-PPV), Poly[(5,6-dihydro-5-octyl-4,6-dioxo-4H-thieno[3,4-C]pyrrole-1,3-diyl){4,8-bis[(2-butyloctyl)oxy]benzo[1,2-b:4,5-b′]dithiophene-2,6-diyl}] (PBDTBO-TPDO), Poly[(5,6-dihydro-5-octyl-4,6-dioxo-4H-thieno[3,4-c]pyrrole-1,3-diyl)[4,8-bis[(2-ethylhexyl)oxy]benzo[1,2-b:4,5-b′]dithiophene-2,6-diyl]] (PBDT(EH)-TPD(Oct), Poly[(5,6-dihydro-5-octyl-4,6-dioxo-4H-thieno[3,4-c]pyrrole-1,3-diyl)[4,8-bis[(2-ethylhexyl)oxy]benzo[1,2-b:4,5-b′]dithiophene-2,6-diyl]] (PBDT-TPD), Poly[1-(6-{4,8-bis[(2-ethylhexyl)oxy]-6-methylbenzo[1,2-b:4,5-b′]dithiophen-2-yl}-3-fluoro-4-methylthieno[3,4-b]thiophen-2-yl)-1-octanone] (PVDTTT-CF), Poly[[5-(2-ethylhexyl)-5,6-dihydro-4,6-dioxo-4H-thieno[3,4-c]pyrrole-1,3-diyl](4,4′-didodecyl[2,2′-bithiophene]-5,5′-diyl)], Poly[N-9′-heptadecanyl-2,7-carbazole-alt-5,5-(4′,7′-di-2-thienyl-2′,1′,3′-benzothiadiazole)] (PCDTBT), Poly[(5,6-dihydro-5-octyl-4,6-dioxo-4H-thieno[3,4-c]pyrrole-1,3-diyl)[4,4-bis(2-ethylhexyl)-4H-silolo[3,2-b:4,5-b′;]dithiophene-2,6-diyl]] (PDTSTPD), Poly[(5,6-difluoro-2,1,3-benzothiadiazol-4,7-diyl)-alt-(3,3′″-di(2-octyldodecyl)-2,2′,5′,2″,5″,2′″-quaterthiophen-5,5′″-diyl)] (PffBT4T-2OD), Poly[2,7-(9,9-dioctylfluorene)-alt-4,7-bis(thiophen-2-yl)benzo-2,1,3-thiadiazole] (PFO-BT), Poly([2,6′-4,8-di(5-ethylhexylthienyl)benzo[1,2-b;3,3-b]dithiophene]{3-fluoro-2[(2-ethylhexyl)carbonyl]thieno[3,4-b]thiophenediyl}) (PCE-10), Poly(3-dodecylthiophene-2,5-diyl) (P3DDT), Poly(3-octylthiophene-2,5-diyl) (P3OT), Poly[2,7-(9,9-dioctyl-dibenzosilole)-alt-4,7-bis(thiophen-2-yl)benzo-2,1,3-thiadiazole] (PSiF-DBT), Poly({4,8-bis[(2-ethylhexyl)oxy]benzo[1,2-b:4,5-b′]dithiophene-2,6-diyl}{3-fluoro-2-[(2-ethylhexyl)carbonyl]thieno[3,4-b]thiophenediyl}) (PTB7), Poly[[2,3-bis(3-octyloxyphenyl)-5,8-quinoxalinediyl]-2,5-thiophenediyl] (TQ1), and poly(3-hexylthiophene-2,5-diyl) (P3HT). Combinations of the foregoing electron donor materials may also be used.

Suitable electron acceptor materials include but are not limited to fullerene-based materials such as fullerene-C₆₀, [5,6]-fullerene-C₇₀, fullerene-C₈₄, [6,6]-thienyl C₆₁ butyric acid methyl ester ([60]ThPCBM), 4-(1′,5′-Dihydro-1′-methyl-2′H-[5,6]fullereno-C₆₀-Iₕ-[1,9-c]pyrrol-2′-yl)benzoic acid, [6,6]-phenyl-C₆₁-butyric acid methyl ester (PCBM), [6,6]-phenyl-C₆₁-butyric acid octyl ester (PCBO), [6,6]-phenyl-C₇₁-butyric acid methyl ester ([70]PCBM), [6,6]-pentadeuterophenyl C₆₁ butyric acid methyl ester (d₅-PCBM), 1′,1″,4′,4″-tetrahydro-di[1,4]methanonaphthaleno[1,2:2′,3′,56,60:2″,3″][5,6]fullerene-C₆₀ (ICBA), 1′,4′-dihydro-naphtho[2′,3′:1,2][5,6]fullerene-C₆₀ (ICMA), and [6.6] diphenyl-C₆₂-bis(butyric acid methyl ester)(bis[60]PCBM); n-channel organic semiconductors such as perylene-3,4,9,10-tetracarboxylic dianhydride and copper(II) 1,2,3,4,8,9,10,11,15,16,17,18,22,23,24,25-hexadecafluoro-29H,31H-phthalocyanine (F₁₆CuPc); and n-type polymer semiconductors such as poly(benzimidazobenzophenanthroline). Combinations of the foregoing electron acceptor materials may also be used.

While not required, a buffer layer may also be included in the photovoltaic cell. In one example, a buffer layer may be disposed adjacent the second electrically-conductive layer, such that it is between the second electrically-conductive layer and the at least one photovoltaic active layer. When the second electrically-conductive layer is the anode, the aforementioned buffer layer (also sometimes called an anode buffer layer) should be stable and translucent. In embodiments, the anode buffer layer may transport positive charge carriers efficiently (hole transporting), block negative charge carriers (electron blocking), and/or smooth the ITO surface to reduce surface recombination. When the second electrically-conductive layer is the cathode, the aforementioned buffer layer (also sometimes called a cathode buffer layer) should be stable and translucent. In embodiments, the cathode buffer layer may transport negative charge carriers efficiently (electron transporting) and/or block positive charge carriers (hole blocking).

A buffer layer may also be disposed adjacent the first electrically-conductive layer, such that it is between the first electrically-conductive layer and the at least one photovoltaic active layer. When the first electrically-conductive layer is the cathode, the aforementioned (cathode) buffer layer may transport negative charge carriers efficiently (electron transporting) and/or block positive charge carriers (hole blocking). When the first electrically-conductive layer is the anode, the (anode) buffer layer may transport positive charge carriers efficiently (hole transporting), block negative charge carriers (electron blocking), and/or smooth the ITO surface to reduce surface recombination.

The anode buffer layer may comprise a metal oxide such as vanadium oxide (V₂O₅), molybdenum oxide (MoO₃), tungsten oxide (WO₃), or nickel oxide (NiO), or a p-type interfacial layer such as (poly(3,4-ethylenedioxythiophene) doped with poly(styrene sulfonate) (PEDOT:PSS), Poly[2,5-bis(3-tetradecylthiophen-2-yl)thieno[3,2-b]thiophene] (PBTTT-C14), Poly[2,7-(9,9-dioctyl-dibenzosilole)-alt-4,7-bis(thiophen-2-yl)benzo-2,1,3-thiadiazole] (PSiF-DBT), sulfonated poly(diphenylamine), polyaniline (PANI), or polyaniline-poly(styrene sulfonate) (PANI-PSS), or a mixture of the foregoing.

The cathode buffer layer may comprise a metal oxide such as titanium oxide (TiOₓ) or zinc oxide (ZnO), an alkali metal salt such as lithium fluoride, a small molecule material such as bathophenanthroline (BPhen), 1,3,5-tris(2-N-phenylbenzimidazolyl) benzene (TPBi), tris-8-hydroxy-quinolinato aluminum (Alq₃), or bathocuproine (BCP), or a combination thereof.

Generally, as used herein, a “decorative paper layer” is a visible outer layer in the (final, assembled) laminate. A decorative paper layer may have decorative colors and/or designs. An overlay paper layer may be disposed above the decorative paper layer provided that the decorative paper layer is at least partially visible through the overlay paper layer. When one or more of these layers is present, the translucent insulating layer is disposed thereover.

A laminate with a photovoltaic cell embedded therein has particularly useful characteristics, including: the ability to provide a plurality of photovoltaic cells in a space-efficient manner; favorable heat-dissipation properties due to the lack of insulating air inside the laminate and optional use of fillers with high heat transfer coefficients (e.g., ceramics such as aluminum nitride, aluminum oxide, boron nitride, and combinations thereof) in the resin formulations used to prepare the resin-impregnated paper layers such that heat transfer away from the photovoltaic cell is enhanced, effectively turning the laminate surfacing material into an efficient heat sink and facilitating the utilization of the photovoltaic cell; unexpectedly and surprisingly advantageous electrical characteristics of the photovoltaic cell even after undergoing an HPL process compared to a comparable photovoltaic cell; improvement of operational life of the photovoltaic cell; and the ability to be integrated into almost any surface (e.g., countertop, particularly exterior countertop, exterior window frame, roofing tiles, exterior cladding, etc.). It is envisioned that the laminates with a photovoltaic cell embedded therein will be particularly useful in exterior applications, such as roofing tiles and exterior cladding, as these applications will facilitate transforming natural sunlight into electrical energy. Because the resin-impregnated paper layers and the insulating are expected to provide a robust, durable enclosure for the photovoltaic cell(s), degradation of the photovoltaic material(s) is expected to be minimized and the lifetime of the photovoltaic cells is expected to be significantly increased.

The photovoltaic cell may be formed by providing (e.g., disposing) an electrically-conductive material (e.g., electrically-conductive ink) onto paper layers (e.g., kraft paper, tissue paper, etc.) having via holes cut through the paper layers for electrically coupling sub-elements or layers of the photovoltaic cell. Disposing (e.g., printing) the electrically-conductive material onto paper allows the paper fibers to act as a reinforcement for the various layers of the photovoltaic cell, helping to prevent breakage of the photovoltaic cell due to shrinkage or expansion due to various environmental conditions. The layers of the photovoltaic cell may be stacked and encapsulated between discrete paper layers and the insulating layer using a lamination process. While low pressure lamination may be used to prepare laminates according to the disclosure, a high pressure lamination process including a re-cooling stage (referred to herein as “high pressure lamination process”) is preferred. In a high pressure lamination process, a simultaneous pressing and heating process is conducted at relatively high levels of heat and pressure, such as temperatures greater than or equal to 125° C. and at least 5 mega Pascals (MPa) of pressure, typically for a press cycle of 30-50 minutes. Every press cycle includes both heating and cooling of the press platens, such that the pressure is maintained during both heating and cooling. While not intending to be bound by theory, it is theorized that a high pressure lamination process, specifically, maintaining the pressure during both heating and cooling is important for achieving the surprising electrical performance shown herein.

As described herein, the photovoltaic cell is “encapsulated” or substantially protected by providing the first electrically-conductive layer for the photovoltaic cell on at least one paper layer, providing the photovoltaic active material layer(s) over the first electrically-conductive layer, and providing the second electrically-conductive layer over the photovoltaic active material layer(s), disposing a translucent insulating layer above the second electrically-conductive layer, thereby forming a laminate stack, and conducting a lamination process on the laminate stack such that the photovoltaic cell is at least partially protected or shielded from ambient atmosphere by encapsulation within the laminate by the paper layer(s) and the overlying insulating layer. When laminate stacks are exposed to the heat and pressure in the lamination process, the mechanical strength of the photovoltaic cell may be significantly enhanced. The lamination process, in particular high pressure lamination, has been shown to make the photovoltaic cell more efficient. Without intending to be bound by theory, it is theorized that the electronic donor and acceptor active material layer(s) and any organic buffer layers of the photovoltaic cell are able to achieve enhanced electrical contact with one another thereby enhancing exciton formation, charge carrier transport, and/or reducing surface recombination. In addition, when conductive vias are present in a photovoltaic device, the electrically-conductive tracks have improved track densification, which achieves surprisingly higher conductivities than through other conventional manufacturing techniques.

Initiating the high pressure lamination process after stacking the layers of the photovoltaic cell between the paper layer(s) and the translucent insulating layer cures the layers included in the laminate and the translucent insulating layer simultaneously, which eliminates the conventional need for using an adhesive to adhere together layers that have individually been fully cured. The high pressure lamination process allows for accurate control of temperature and pressure (e.g., heating and cooling cycles) in order to control the rate of dimensional change of layers and surprisingly leads to enhanced electrical characteristics for the photovoltaic cell within the laminate. In preferred embodiments, the laminates undergo the high pressure lamination process at relatively high levels of heat and pressure, such as at a temperature in the range of 120° C.-145° C. and a pressure in the range of 70-100 bar, for a press cycle of 10-20 minutes. During the cool cycles of the high pressure lamination process, the temperature may drop to less than 40° C.

Various methods for preparing laminates with the photovoltaic cell embedded within the laminate may be used. The methods include forming via holes through paper layers, disposing (e.g., inkjet printing, flexographic printing, gravure printing, screen printing, extrusion printing, and the like) sub-elements or layers of the photovoltaic cell onto the paper layers, and providing vias through the paper layers at selected via hole locations with an electrically-conductive material to electrically couple various layers of the photovoltaic cell. Factors in determining the selected locations may include efficient layout design, avoiding shorting layers of the photovoltaic cell, etc. The layers of the photovoltaic cell may be stacked and encapsulated between the paper layers by subjecting the laminate to the high pressure lamination process, which surprisingly results in advantageously enhanced densification of the electrically-conductive material and excellent conductivity. It should be noted that the same electrically-conductive material may be used for one of the electrically-conductive layers of the photovoltaic cell and the vias, but different electrically-conductive materials may also be used.

In one embodiment, a method of making a laminate having a photovoltaic cell embedded within the laminate comprises providing a plurality of kraft paper layers; providing a photovoltaic cell over the plurality of treated kraft paper layers, the photovoltaic cell comprising a first electrically-conductive layer, at least one photovoltaic active material layer disposed over the first electrically-conductive layer, and a second electrically-conductive layer disposed over the photovoltaic active material layer, each of the photovoltaic cell layers being arranged over the plurality of kraft paper layers and on an uppermost kraft paper layer of the plurality of kraft paper layers; providing a translucent insulating layer over the second electrically-conductive layer such that the translucent insulating layer is disposed above the photovoltaic cell; and compressing and, heating during at least a portion of the compressing, a laminate stack comprising the plurality of kraft paper layers, the first electrically-conductive layer, the photovoltaic active material layer, the second electrically-conductive layer, and the translucent insulating layer, according to a lamination process, thereby making the laminate with the photovoltaic cell embedded within the laminate. The plurality of kraft paper layers typically comprise one or more treated kraft paper layers, e.g., three sheets of phenol-formaldehyde resin-impregnated kraft paper.

Optionally, the stack may include one or more untreated kraft paper layers. Including untreated kraft paper layers can be useful when frangible components are included in the laminate such that a “cushioning effect” is desired, for example, when a pre-fabricated (already) encapsulated photovoltaic cell is included in the laminate.

A glue film layer may be disposed below an untreated kraft paper layer so as to allow a sufficient amount of resin to saturate the laminate during a lamination process, in order to provide sufficient mechanical strength to the final formed laminate. By providing the first electrically-conductive layer on untreated kraft paper, significantly improved alignment of holes formed in the stack can be achieved than when the first electrically-conductive layer is disposed on resin-impregnated paper layers. A glue film layer as used herein is a layer having a sufficient amount of thermoset resin to saturate an adjacent untreated paper layer (e.g., a decorative paper layer or a kraft paper layer). Typically, a glue film layer will comprise a paper layer having between 30-80 percent by weight of a thermoset resin. Preferably, the thermoset resin of the glue film comprises phenol-formaldehyde resin.

In manufacturing the laminate, providing the translucent insulating layer over the photovoltaic cell may be carried out by implementing a dual cure transfer film process. Specifically, providing the translucent insulating layer over the photovoltaic cell may be carried out by applying a release film, such as a metal foil release film or a polyethylene terephthalate (PET) release film, the release film being coated with a dual cure resin composition capable of being cured by both UV light and heat. Thus, the dual cure resin composition may include a photoinitiator and a thermal catalyst. For example, the translucent insulating layer may be provided by coating a PET-based release film with 75-140 GSM of a composition including urethane acrylate dual cure resin, a photoinitiator, a thermal catalyst, and a bridging agent (e.g., a melamine acrylate bridging agent). Inclusion of the photoinitiator, the thermal catalyst, and the bridging agent enables the translucent insulating layer to be bonded to other layers within the laminate during the lamination process.

In a first partial cure step, UV radiation converts the dual cure composition into a partially cross-linked composition, but leaves the thermal catalyst active for a subsequent step in which heat is applied. In a second step, such as is common in lamination processes, particularly in high pressure lamination, simultaneous pressing and heating process is conducted at relatively high levels of heat and pressure sufficient for fully curing (or cross-linking) the dual cure resin composition. Thus, in the final laminate, the translucent insulating layer comprises a cross-linked insulating polymer such as urethane acrylate, polyester acrylate, epoxy acrylate, acrylic acrylate, polyether acrylate, or a mixture thereof. The release film may be stripped off the laminate upon completion of the laminate process.

In one aspect, the dual cure resin composition may include a cross-linkable resin such as urethane acrylate, polyester acrylate, epoxy acrylate, acrylic acrylate, polyether acrylate, or a mixture thereof combination with a photoinitiator, a thermal catalyst, and a bridging agent enabling bonding between the cross-linkable dual cure resin and the melamine resin of a decorative layer, for example. Of course, the bridging agent alternatively may enable binding between the cross-linkable dual cure resin and the phenolic-formaldehyde resin of a treated kraft paper layer. Other bridging agents are also contemplated.

Electrically-conductive materials suitable for use in the present disclosure include any material which can be disposed upon paper, such as resin-impregnated paper, and which may be electrically-conductive. In some embodiments, the composition of the electrically-conductive material includes: (i) a particulate, electrically-conductive material; (ii) a binder; and optionally (iii) a microcrystalline cellulose component.

Generally, the particulate, electrically-conductive material may include any one of metals, alloys, electrically-conductive carbons (e.g., electrically-conductive allotropes of carbon, graphites), electrically-conductive polymers (e.g., polypyrrole), electrically-conductive metallized polymers (e.g., metallized polyethylene terephthalates), and combinations thereof. When the first electrically-conductive layer is the cathode as in a conventional OPV cell, the first electrically-conductive material may comprise a low work function metal, for example, calcium, magnesium, aluminum, silver, or a combination thereof. In one aspect, the first electrically-conductive material may comprise particles of silver and/or silver alloys. When the second electrically-conductive layer is the anode as in a conventional OPV cell, the second electrically-conductive layer may comprise a transparent conductive oxide, for example, indium tin oxide (ITO), antimony tin oxide (ATO), indium zinc oxide, gallium zinc oxide, aluminum zinc oxide, gallium aluminum zinc oxide, or a combination thereof. When the first electrically-conductive layer is the anode as in an inverted OPV cell, the first electrically-conductive material may comprise a relatively high work function metal such as gold or silver and one of the foregoing transparent conductive oxides may be used as the cathode.

Electrically-conductive ink compositions which may be disposed to provide electrically-conductive material on a paper layer and are thus suitable for use in various embodiments of the present disclosure typically include particles comprising metal, metal alloys, electrically-conductive carbon, or other electrically-conductive materials such as polymers, in a carrier medium which may include other polymers, solvents and additives. Various known methodologies such as inkjet printing, screen printing, flexographic printing, gravure printing, or extrusion printing may be used to dispose the electrically-conductive ink compositions on a substrate. In an implementation, electrically-conductive material (e.g., electrically-conductive ink) is disposed in the shape of electrically-conductive layers on a paper layer, a buffer layer, or a photovoltaic active layer. Throughout this disclosure, references to electrically-conductive material or ink should be understood to include the electrically-conductive material or ink itself in addition to the layer of electrically-conductive particles left behind after the electrically-conductive material or ink has dried.

One embodiment of an electrically-conductive ink composition suitable for providing the particulate electrically-conductive material is an electrically-conductive ink composition comprising: (i) a particulate, electrically-conductive material; (ii) a carrier liquid; (iii) a polymer binder; and (iv) a microcrystalline cellulose component. Another embodiment of an electrically-conductive ink composition suitable for providing the particulate electrically-conductive material is an electrically-conductive ink composition comprising: (i) a particulate, electrically-conductive material; (ii) a carrier liquid; (iii) a polymer binder; and (iv) a microcrystalline cellulose component; wherein the particulate, electrically-conductive material comprises a component selected from the group consisting of silver and silver alloys; and wherein the microcrystalline cellulose component is present in an amount of from about 0.05% to about 10% by weight based on the ink composition and has an average particle size of from about 20 to about 100 μm. In certain embodiments of the disclosure, the microcrystalline cellulose component may include two or more microcrystalline celluloses having different average particle sizes. As noted above, disposing methods such as inkjet printing, flexographic printing, gravure printing, screen printing, and extrusion printing may be used to dispose the electrically-conductive material onto the paper layers, such as kraft paper and overlay paper, but depending on the type of paper, the electrically-conductive material may or may not penetrate completely through the paper.

If kraft paper (i.e., unbleached paper that is between 50-400 GSM (or g/m²)) is used, and an electrically-conductive ink composition is disposed thereon, the electrically-conductive material may penetrate halfway through the kraft paper, whereas if paper having less than half the basis weight of kraft paper is used (e.g., bleached paper that is between 10-50 GSM), and an electrically-conductive ink composition is disposed thereon, the electrically-conductive material will typically penetrate completely through the paper. As such, in order to couple electrically-conductive material provided on different layers of kraft paper together, apertures can be cut at least halfway through the kraft paper, so that electrically-conductive material disposed over a top surface of the kraft paper penetrates halfway through the first kraft paper to form a via and establish an electrical connection with a same type or different type electrically-conductive material provided on a top surface of a second kraft paper layer underlying the first kraft paper layer. Because disposed electrically-conductive material may penetrate completely through some paper, it is not necessary to cut apertures to form a via in all paper. Once disposed, the electrically-conductive material may be subject to the high pressure lamination process involving pressing at elevated temperature and pressure described herein.

Conductive traces comprising the electrically-conductive materials described above may be provided on the paper layer used as the “print base” for the photovoltaic cells. The conductive traces may be in electrical contact with vias formed in the laminate papers layers and/or with the photovoltaic cells printed thereon, to allow electrical connection between the photovoltaic cells and a battery or other storage device. It should be understood that throughout this application via holes are alternatively referred to as vias once conductive material is included therein and a lamination process that establishes electrical contact between conductive elements is performed.

The laminate in accordance with the various embodiments of the present disclosure may include one or more electrical contact pads protruding there from which allow an electrical connection to be established from the exterior of the laminate to one or more of a conductive trace (that is in electrical contact with an electrically-conductive layer), a via (that is in electrical contact with an electrically-conductive layer), or an electrically-conductive layer. Thus, in embodiments in which electrical contact pads are provided in contact with electrically-conductive layers, vias may not be necessary. In various embodiments, the laminate may include an electrical contact pad coupled to a first via providing a site for making an electrical connection to a first terminus of the first electrically-conductive material, and a second electrical contact pad coupled to a second via providing a site for making an electrical connection to a second terminus of the second electrically-conductive material. In the various embodiments of the present disclosure, the laminate may further be coupled to a component or components connected to the electrical contact pads on the exterior of the laminate which component(s) are configured to accept voltage input from the photovoltaic cell such that the electrically-conductive material(s) provided current to the component(s). Such components may include, but are not limited to active electronic components (e.g., active transistors and integrated circuits) and/or a passive electronic components (e.g., resistors and capacitors). Electrical contact with the vias may also be established by coupling any electrically-conductive material to the electrical contact pads using various structures including but not limited to metal tabs, screws, prongs, cylindrical receptacles, spring-loaded pins, etc. Additionally, methods of establishing permanent electrical contact can be established by affixing an external component or conductor to the electrical contact pads by soldering or the use of electrically-conductive adhesives.

A laminate's paper layers may be impregnated with resin such that the paper layers, when stacked and compressed in the high pressure lamination, can be cured or cross-linked. The resin can be a thermoset resin such that the paper layers in a stacked relationship can be compressed and heated to cure the thermoset resin. Generally, resin-impregnated paper layers are impregnated with any suitable thermoset resin including, but not limited to, acrylics, polyesters, polyurethanes, phenolics, phenol-formaldehydes, urea-formaldehydes, aminoplastics, melamines, melamine formaldehydes, diallyl-phthalates, epoxides, polyimides, cyanates, and polycyanurates, or copolymers, terpolymers or combinations thereof. In the laminates according to the instant disclosure, phenol-formaldehydes and epoxides are typically used for impregnating kraft paper.

In some implementations, resin-impregnated paper layers which are core layers are impregnated with a phenolic and/or epoxy resin, such as, for example, a phenolic-formaldehyde resin. Impregnating paper layers with a resin can be carried out in any suitable manner sufficient to apply a controlled quantity of resin to the paper, including but not limited to, screen printing, rotary screen printing, dip and squeeze, dip and scrape, reverse roll-coating, Meyer bar, curtain coating, slot-dye and gravure roller. The weight percentage of resin applied, relative to the weight of the paper layer as measured on an oven dried basis, may be in the range of about 5 to 75%, with a preferred resin content percent (determined relative to final weight) of about 15-45%. As the resins used in the impregnating step are normally aqueous or solvent based solutions, it is common in the laminating process to include a paper drying stage to reduce the paper solvent loading. In the various embodiments of the present disclosure, the weight percent level of residual solvent in the impregnated paper may be 2.5-15% with a typical level of about 5%. As used herein, curing can refer to both curing of a resin in the sense of its irreversible setting, or the crosslinking of other polymers with a separate cross-linker or by various forms of energy, or any means of fixing the resin when the laminate surfacing material is in its compressed form such that the photovoltaic cell is encapsulated and will remain so during normal operation.

Suitable papers which may be used in resin-impregnated paper layers in accordance with the various embodiments of the present disclosure include but are not limited to: cellulose fiber, synthetic woven or non-woven fiber, or/and microfiber or/and nanofiber, mixtures of cellulose or/and synthetic fiber based papers or/and mineral fiber based papers or/and glass fiber based papers, coated or non-coated, pre-impregnated or non pre-impregnated that could be generally used for the production of laminates. In various embodiments of the present disclosure, paper suitable for use in resin-impregnated paper layers may have at least one of the following properties: a minimum wet strength in the machine direction of 1400 cN/30 mm in accordance with the test method of the International Standard DIN ISO 3781, a Klemm absorbency range (capillary rise) in the machine direction of 30 to 90 mm/10 min in accordance with the test method of the International Standard DIN ISO 8787 with a preferred absorbency of 45 mm/10 min, Ash content 0 to 50% depending of the intrinsic nature of the paper used in accordance with the test method of the International Standard Din ISO 2144, a basis weight range of 10 to 400 GSM at moisture content range of 2 to 8% in accordance with the test method of the International Standard DIN ISO 536, a pH (on hot extract) between about 4 to 9 in accordance with the test method of the International Standard DIN ISO 6588. In various embodiments of the present invention, papers comprising at least a portion of recycled materials may be used.

In various preferred embodiments of methods of manufacturing laminates having a photovoltaic cell encapsulated within the laminate in accordance with the present disclosure, a high pressure lamination process may be employed. In accordance with such various preferred embodiments, the multiple layers, including both paper layers and layers of the photovoltaic cell according to any of the previously described embodiments are positioned in a stacked relationship between two pressing plates. In such a high pressure lamination process, the plates are then pressed to a specific pressure of at least 50 bar. The temperature is then raised to greater or equal to 125° C., typically between 130-145° C. The plates are then held at the elevated pressure and temperature for a period of time suitable for curing the resins contained within the resin-impregnated paper layer(s), carried on the release film for forming the translucent insulating layer, and/or glue layers. The temperature may then be lowered to 40° C. or below, while maintaining the elevated pressure. The typical cycle time under pressure is between about 30 and about 50 minutes. Upon achieving a temperature of 40° C., the pressure on the plates may then be reduced to zero gauge pressure. While it is important to take care in ensuring that the stacked layers are aligned where an electrically-conductive connection between adjacent electrically-conductive materials through a via (an aperture) in an intervening layer is to be established, the layers need not otherwise be placed in perfect edge to edge alignment, as a post-pressing trimming may be carried out to shape the final surfacing material.

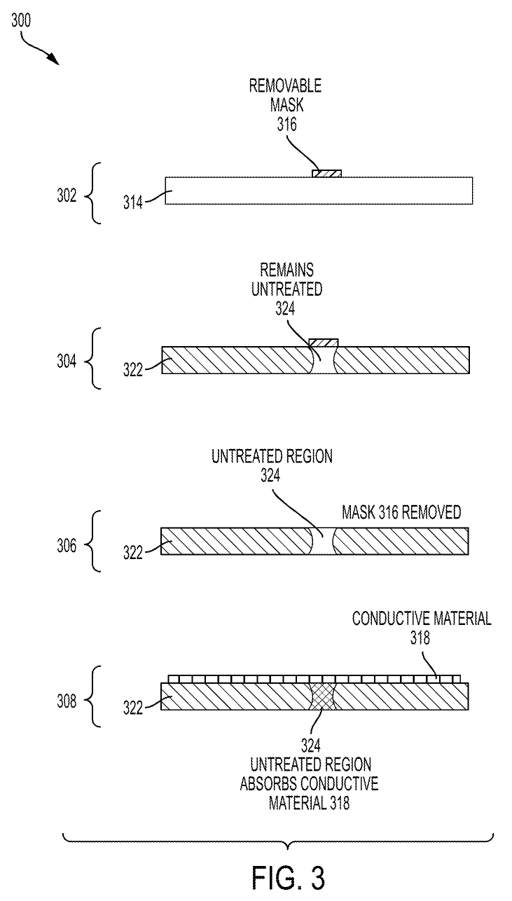

While resin-impregnated layers are typically used to prepare the laminates comprising a photovoltaic cell embedded or encapsulated within the laminate, alternatively, paper layers having pressure-sensitive adhesives thereon can be compressed with the pressure-sensitive adhesives in a facing relationship to form a comparable laminate structure. In such a process, a mask can be applied at any locations where vias are desired in the final laminate product to facilitate via formation, similar to the procedure described herein with reference to FIG. 3.

Other examples of electronic components that may be included in the core of the laminate include components that receive current from the photovoltaic cell. The electronic component may be an active electronic component (e.g., active transistors and integrated circuits) and/or a passive electronic component (e.g., resistors and capacitors) such that the electrically-conductive material(s) provide current to the electronic component. Each of these components can be disposed between discrete paper layers of the laminate and electrically coupled to the photovoltaic cell in the laminate by a via.

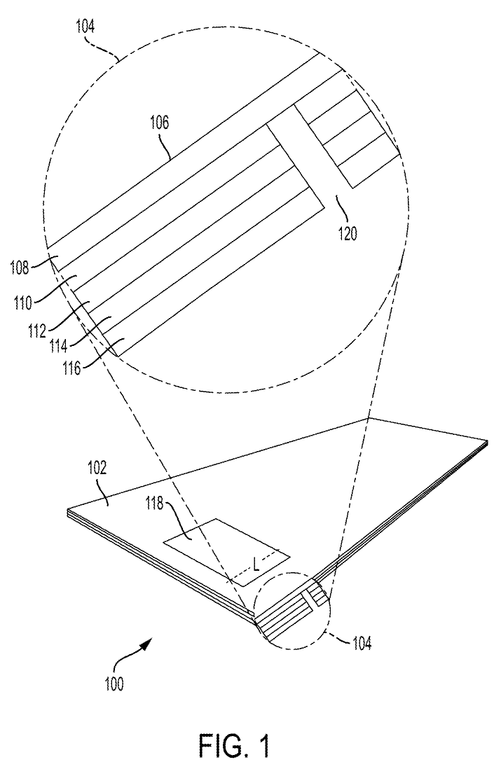

FIG. 1 is a schematic diagram of an example of a laminate 100 having a photovoltaic cell 108 embedded within the laminate 100 and encapsulated between a translucent insulating layer 106 and multiple kraft paper layers 110, 112, 114, and 116, the laminate taking the form of exterior cladding 102. Laminates according to the disclosure may also take the form of other types of surfaces (e.g., countertop, particularly exterior countertop, exterior window frame, roofing tiles, exterior cladding, etc.).

Exploded cross-sectional view 104 further illustrates a cross-section taken along line L of designated area 118 to better illustrate the photovoltaic cell 108 embedded within the laminate 100. The photovoltaic cell 108 comprises a first electrically-conductive layer, at least one photovoltaic active material layer disposed over the first electrically-conductive layer, and a second electrically-conductive layer disposed over the photovoltaic active material layer, the second electrically-conductive layer comprising a translucent electrically-conductive material, each of the photovoltaic cell layers being arranged over the plurality of kraft paper layers 110, 112, 114, and 116 and on an uppermost kraft paper layer 110 of the plurality of kraft paper layers 110, 112, 114, and 116. A buffer layer (not shown) may be disposed adjacent the second electrically-conductive layer, such that it is between the second electrically-conductive layer and the at least one photovoltaic active layer. A buffer layer (not shown) may also be disposed adjacent the first electrically-conductive layer, such that it is between the first electrically-conductive layer and the at least one photovoltaic active layer. A via 120 in electrical contact with the first electrically-conductive layer of the photovoltaic cell 108 advantageously allows various electrical connections to harvest energy from the cell. In the illustrated embodiment, the photovoltaic cell is printed in designated area 118 of the laminate 100. Of course, the laminate 100 may further include additional photovoltaic cells embedded therein.

In use, the laminate 100 may be equipped with an active electronic component (e.g., active transistors and integrated circuits) and/or a passive electronic component (e.g., resistors and capacitors) such that the photovoltaic cell 108 provides current to the electronic component. The electronic component may be electronically coupled to photovoltaic cell 108 to be provided with voltage. In at least one implementation, an additional electronic device may be physically encapsulated within laminate 100.

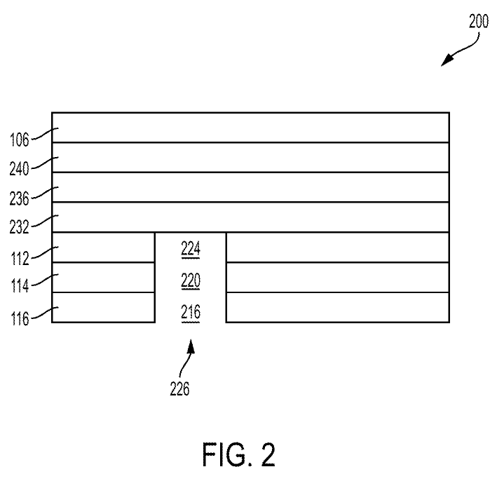

FIG. 2 shows a further example of a laminate 200 having a photovoltaic cell disposed within the laminate 200. Specifically, laminate 200 includes at least one paper layer 112 (e.g., kraft paper) and a translucent insulating layer 106, as described in FIG. 1, between which layers of the photovoltaic cell, i.e., electrically-conductive layers 232 and 240 and at least one photovoltaic active material layer 236 are disposed. The paper layer 112 may be impregnated with resin, such as phenolic resin. The translucent insulating layer 106 may be a cross-linked polymer such as urethane acrylate. The layers of the photovoltaic cell may be disposed by various methodologies, such as inkjet printing, screen printing, flexographic or gravure printing, extrusion printing, and three-dimensional printing. As illustrated, the laminate 200 also includes additional paper layers 114, 116 comprising treated kraft paper. A decorative paper layer (not shown), such as a print sheet treated with melamine resin, can optionally be included between the second electrically-conductive layer 240 and the translucent insulating layer 106. The additional paper layers 114, 116 may be impregnated with resin, such as phenolic resin.

Any one or more of the paper layers may include a via hole that may be formed or cut through the entire paper layer. For example, paper layer 112 includes via hole 224. Similarly, paper layers 114, 116 include via holes 220 and 216, respectively. The via holes described may be formed, cut through, or punched through, such as by a mechanical device or a laser, when the paper layers 112, 114, and 116 are stacked on top of each other, so that the via holes are vertically aligned and readily filled with electrically conductive material to form via 226. For example, in the illustrated embodiment, via holes 216, 220, and 224 are vertically aligned.

An electrically-conductive material is disposed over paper layer 112 to form a first electrically-conductive layer 232 of the photovoltaic cell. The first electrically-conductive layer 232 forms the cathode in the conventional photovoltaic cell structure and the anode in the inverted structure as described above. The electrically-conductive material may be deposited directly over the paper layer 112. Paper layer 112 may be heavily calendared to better serve as a print base layer for the photovoltaic cell. The first electrically-conductive layer 232 is electrically coupled to an electrically-conductive material that fills first via 226 after a lamination process.

A photovoltaic active material layer 236 may be disposed over the first electrically-conductive layer 232 of the photovoltaic cell. The photovoltaic active material layer 236 may comprise any suitable molecule or polymer capable of converting the incident light into electrical energy by the photovoltaic effect. It should be understood that the at least one photovoltaic active material layer 236 comprises electron donor and acceptor materials, which may be provided by the same or different (mixture) materials and by the same or different layers, as known for a conventional photovoltaic cell. Of course, buffer layers may also be incorporated in device 200 as described herein.

A translucent electrically-conductive material may be disposed over photovoltaic active material layer 236 to form the second electrically-conductive layer 240. As mentioned above, the second electrically-conductive layer 240 forms the anode in the conventional photovoltaic cell structure and the cathode in the inverted structure as described above.

Lastly, the translucent insulating layer 106 may be disposed over the second electrically-conductive layer 240, thereby encapsulating the photovoltaic device comprising the first electrically-conductive layer, the photovoltaic active material layer, and the second electrically-conductive layer within the laminate.

After a lamination process, the paper layer 112 and the translucent insulating layer 106 encapsulate the first electrically-conductive layer 232, the photovoltaic active material layer 236, and the second electrically-conductive layer 240 within the laminate 200. Specifically, after the layers described above undergo a lamination process, preferably a high pressure lamination process, the resin that may be impregnated in the paper layer 112 consolidates and bonds together (by heat and pressure) the first electrically-conductive layer 232, the photovoltaic active material layer 236, and the second electrically-conductive layer 240 into a substantially continuous resin structure having significant mechanical structure, thereby forming the laminate 200.

Laminate 200 as illustrated includes paper layers 112, 114, and 116, optionally decorative paper layer 110, and a translucent insulating layer 106, but it should be understood that the present disclosure is not limited to the precise configuration shown. For instance, additional paper layers may be stacked below paper layer 116. Such additional paper layers may provide space for embedding one or more electrical components to be powered on from the photovoltaic cell disposed within the laminate structure. As another example, a substrate, such as glass, may be disposed over the translucent insulating layer 106 to further protect and encapsulate the laminate 200.

FIG. 3 illustrates an example operation 300 for forming an electrical via, such as vias 226 of FIG. 2 between paper layers in a laminate using a masking technique. A paper layer for a laminate including a photovoltaic cell may be prepared with a sheet of untreated kraft paper 314 (e.g., paper layer 112 of FIG. 2) and partially covered with a removable mask 316 on one side of untreated paper sheet 314 at a location of a desired electrical connection through the paper 314 at operation 302.

A resin-treating operation 304 impregnates the kraft paper 314 with a resin to form resin-treated paper 322. The mask 316 protects a portion 324 of the resin-treated kraft paper 322 during the resin-treating operation 304 and the portion 324 does not become impregnated with the resin. A removing operation 306 removes the mask 316, exposing the untreated region 324 of the resin-treated kraft paper 322.

A disposing operation 308 disposes electrically-conductive material (e.g., the first electrically-conductive material 318) onto the untreated region 324 of the resin-treated kraft paper 322. The electrically-conductive material saturates untreated region 324, but does not saturate the resin-treated region of kraft paper 314, thereby allowing for electrical conductivity through the paper 314.

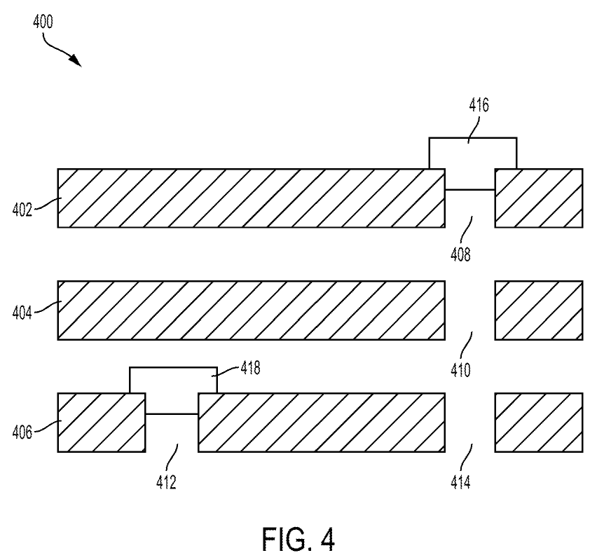

FIG. 4 illustrates an example operation 400 for forming an electrical via between layers in a laminate using a hole cutting technique. A hole forming operation 400 forms a via hole in a layer of a laminate. For example, hole forming operation 400 may form via holes 408 and 410 in layer 406. An electrically-conductive material may fill via hole 408, to electrically couple to layer 404 after a lamination process is conducted. Similarly, an electrically-conductive material may fill via 410 to electrically couple to layer 402 after a lamination process is conducted. A high pressure lamination process may then apply high heat and pressure to the stack of layers arranged in hole forming operation 400 to encapsulate the laminate.

FIG. 5 compares I-V characteristics of a conventional encapsulated photovoltaic cell with that of a laminate having an already encapsulated photovoltaic cell disposed within the laminate (i.e., the first paper layer 112 and the translucent insulating layer 106 encapsulating an encapsulated photovoltaic cell comprising a polyethylene terephthalate insulating later, a first electrically-conductive layer 232, the at least one photovoltaic active material layer 236, and the second electrically-conductive layer 240). Light intensity, temperature, and the distance from light source were kept constant when collecting data to generate I-V curves 602 and 604. Curve 602 corresponds to an encapsulated photovoltaic cell, and curve 604 corresponds to a laminate having an already encapsulated photovoltaic cell disposed within the laminate that further includes a translucent insulating layer 106. As can be seen in I-V curve 602, after receiving incident light, the I-V curve 602 of the encapsulated photovoltaic cell shifts into the fourth quadrant, evidently because the photovoltaic cell begins to generate power (P=V×I). However, as shown in I-V curve 604, after receiving incident light, the I-V curve 604 of the laminate encapsulating the photovoltaic cell unexpectedly and surprisingly shifts deeper into the fourth quadrant, demonstrating that the laminate generates even more power. The I-V curve 604 also shows that the largest current which may be drawn from the laminate (i.e., the short-circuit current when the voltage across the laminate is zero) is approximately 0.08 Amperes, which is greater than the approximate current of 0.06 Amperes which may be drawn from the encapsulated photovoltaic cell, as shown in I-V curve 602. Accordingly, the photovoltaic cell encapsulated within a laminate having the additional translucent insulating layer 106 described in embodiments of the present disclosure surprisingly and unexpectedly has superior I-V characteristics than a conventional encapsulated photovoltaic cell that does not include a translucent insulating layer. This is a particularly unexpected and surprising result given that the presence of two distinct insulating layers in the laminate would be expected to significantly degrade performance.

As used herein, the singular terms “a” and “the” are synonymous and used interchangeably with “one or more” and “at least one,” unless the language and/or context clearly indicates otherwise. Accordingly, for example, reference to “a paper layer” or “the paper layer” herein or in the appended claims can refer to a single paper layer or more than one paper layer. Additionally, all numerical values, unless otherwise specifically noted, are understood to be modified by the word “about.”

For simplicity and clarity of illustration, elements in the figures are not necessarily to scale, and the same reference numbers in different figures denote the same elements. For clarity of the drawing, layers and electrically-conductive materials may be shown as having generally straight line edges and precise angular corners. However, those skilled in the art understand that the edges need not be straight lines and the corners need not be precise angles.

Certain terminology is used in the following description for convenience only and is not limiting. Ordinal designations used herein and an it appended claims, such as “first”, “second”, “third”, etc., are solely for the purpose of distinguishing separate, multiple, similar elements (e.g., a first paper layer and a second paper layer), and do not import any specific ordering or spatial limitations unless otherwise required by context.

The applications and benefits of the systems, methods and techniques described herein are not limited to only the above examples. Many other applications and benefits are possible by using the systems, methods and techniques described herein.

Moreover, although the foregoing text sets forth a detailed description of numerous different embodiments, it should be understood that the scope of the patent is defined by the words of the claims set forth at the end of this patent. The detailed description is to be construed as exemplary only and does not describe every possible embodiment because describing every possible embodiment would be impractical, if not impossible. Numerous alternative embodiments could be implemented, using either current technology or technology developed after the filing date of this patent, which would still fall within the scope of the claims.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A laminate having a photovoltaic cell embedded within the laminate, comprising:
a first paper layer;
a first electrically-conductive layer comprising an electrically-conductive material, the first electrically-conductive layer being disposed over the first paper layer;
at least one photovoltaic active material layer disposed over the first electrically-conductive layer;
a second electrically-conductive layer comprising a translucent electrically-conductive material, the second electrically-conductive layer being disposed over the photovoltaic active material layer;
a translucent insulating layer disposed over the second electrically-conductive layer,
wherein the first paper layer and the translucent insulating layer encapsulate the photovoltaic cell comprising the first electrically-conductive layer, the photovoltaic active material layer, and the second electrically-conductive layer within the laminate.

2. The laminate of claim 1, wherein the first paper layer has at least first and second vias through the first paper layer, and wherein the first electrically-conductive layer is electrically coupled to the first via and the second electrically-conductive layer is electrically coupled to the second via, the first and second vias including a further electrically-conductive material therein.

3. The laminate of claim 1, wherein the translucent insulating layer comprises a cross-linked polymer.

4. The laminate of claim 3, wherein the translucent insulating layer comprises urethane acrylate, polyester acrylate, epoxy acrylate, acrylic acrylate, polyether acrylate, or a mixture thereof .

5. The laminate of claim 1, wherein the at least one photovoltaic active material layer comprises both electron donor and electron acceptor materials.

6. The laminate of claim 1, wherein the at least one photovoltaic active material layer comprises a first layer including an electron donor material and a second layer including an electron acceptor material.

7. The laminate of either claim 5wherein a buffer layer comprising an electron blocking layer is disposed adjacent the second electrically-conductive layer.

8. The laminate of either claim 5, wherein a buffer layer is disposed adjacent the second electrically-conductive layer, the buffer layer comprising a metal oxide, or a p-type interfacial layer.

9. The laminate of claim 5, wherein a buffer layer comprising a hole blocking layer is disposed adjacent the first electrically-conductive layer.

10. The laminate of claim 5, wherein the at least one buffer layer is disposed adjacent the first electrically-conductive layer, the buffer layer comprising a metal oxide, an alkali metal salt, or a small molecule material.

11. The laminate of claim 1, wherein the at least one photovoltaic active material layer comprises an electron donor material comprising a small molecule electron donor a polymer electron donor or a combination thereof.

12. The laminate of claim 1, wherein the at least one photovoltaic active material layer comprises an electron acceptor material comprising a fullerene-based material; a n-channel organic semiconductor; a n-type polymer semiconductor or a combination thereof.

13. The laminate of claim 1, wherein the first paper layer is impregnated with a resin material.

14. The laminate of claim 13, wherein the resin material comprises a phenolic resin, an acrylic resin, an epoxy resin, or a combination thereof.

15. The laminate of claim 1, further comprising:
at least a second paper layer disposed on a side of the first paper layer opposite the first electrically-conductive layer, first and second vias traversing through the second paper layer.

16. The laminate of claim 1, wherein the first electrically-conductive layer comprises silver particles.

17. The laminate of claim 1, wherein the first electrically-conductive layer comprises a low work function metal.

18. The laminate of claim 1, wherein the second electrically-conductive layer comprises a transparent conductive oxide.

19. An article comprising the laminate according to claim 1 disposed on a supporting substrate.

20. A method of manufacturing a laminate having a photovoltaic cell embedded within the laminate, the method comprising:
providing a first paper layer;
providing a first electrically-conductive layer over the first paper layer, wherein the first electrically-conductive layer comprises an electrically-conductive material;
providing at least one photovoltaic active material layer over the first electrically-conductive layer;
providing a second electrically-conductive layer over the photovoltaic active material layer, wherein the second electrically-conductive layer comprises a translucent electrically-conductive material;
providing a translucent insulating layer over the second electrically-conductive layer; and
compressing and, heating during at least a portion of the compressing, a laminate stack comprising at least the first paper layer, the first electrically-conductive layer, the photovoltaic active material layer, the second electrically-conductive layer, and the translucent insulating layer according to a lamination process, thereby manufacturing the laminate with the photovoltaic cell.

21. The method of claim 20, further comprising forming at least first and second via holes through the first paper layer.

22. The method of claim 21, further comprising forming first and second vias by filling the first and second via holes with a further electrically-conductive material prior to disposing the translucent insulating layer over the second conductive layer.

23. The method of claim 23, wherein the compressing of the laminate stack electrically connects the first via to the first electrically-conductive layer and the second via to the second electrically-conductive layer.

24. The method of claim 20, comprising forming the translucent insulating layer by:
providing a formulation comprising a resin, a photoinitiator, and a thermal catalyst;
disposing the formulation over a carrier layer; and
partially curing the formulation via exposure to UV radiation, thereby forming a partially cured resin on the carrier layer.

25. The method of claim 24, wherein the translucent insulating layer is provided as the partially cured resin on the carrier layer, and the carrier layer is opposite the side of the second electrically-conductive layer.

26. The method of claim 20, wherein the lamination process is a high-pressure laminate process.

27. The method of claim 20, wherein a platens is used to perform the compressing step and the platens is raised to a temperature in the range of 125° C.-150° C. during the portion of the compressing step.

28. The method of claim 20, wherein a pressure in the range of 5 and 12 mPa is applied during the compressing step.

29. The method of claim 27, wherein the temperature in the range of 125° C.-150° C. is maintained for a period between 10 and 20 minutes.

30. The method of claim 20, wherein heating is not performed during the entirety of the compressing step.

31. The method of claim 20, wherein, after heating and while compressing is being performed, the laminate stack is allowed to cool to a temperature of less than 40° C. under pressure.
